(19) United States
(12) Patent Application Publication
(10) Pub. No.: US 2005/0136657 A1
(43) Pub. Date: Jun. 23, 2005

(54) Film-formation method for semiconductor process

(75) Inventors: Hiroaki Yokoi, Nirasaki-shi (JP); Tetsu Zenko, Nirasaki-shi (JP); Hiroaki Ashizawa, Nirasaki-shi (JP); Tsuyoshi Hashimoto, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/033,406

(22) Filed: Jan. 12, 2005

Related U.S. Application Data
(63) Continuation-in-part of application No. PCT/JP03/08861, filed on Jul. 11, 2003.

(30) Foreign Application Priority Data
Jul. 12, 2002 (JP) 2002-204138
Jan. 7, 2003 (JP) 2003-001254

(51) Int. Cl. H01L 21/44

(52) U.S. Cl. 438/680

(57) ABSTRACT

A film-formation method for a semiconductor process includes pre-coating of covering a worktable with a pre-coat before loading a target substrate into a process chamber, and film formation thereafter of loading the target substrate into the process chamber, and forming a main film on the target substrate. The pre-coating repeats the first and second steps a plurality of times, thereby laminating segment films to form the pre-coat. The first step supplies first and second process gases into the process chamber, thereby forming a segment film containing a metal element on the worktable. The second step supplies the second process gas containing no metal element into the process chamber, thereby exhausting and removing, from the process chamber, a byproduct produced in the first step other than a component forming the segment film.

### CROSS REFERENCE TO RELATED APPLICATIONS

This is a Continuation-in-Part Application of PCT Application No. PCT/JP03/08861, filed Jul. 11, 2003, which was not published under PCT Article 21(2) in English.

This application is based upon and claims the benefit of priority from prior Japanese Patent Applications No. 2002-204138, filed Jul. 12, 2002; and No. 2003-001254, filed Jan. 7, 2003, the entire contents of both of which are incorporated herein by reference.

### BACKGROUND OF THE INVENTION

1. Field of the Invention

The present invention relates to a film-formation method for a semiconductor process, and particularly to a method of forming a film containing a metal element by CVD (chemical vapor deposition) on a target substrate, such as a semiconductor wafer. The term “semiconductor process” used herein includes various kinds of processes which are performed to manufacture a semiconductor device or a structure having wiring layers, electrodes, and the like to be connected to a semiconductor device, on a target substrate, such as a semiconductor wafer or an LCD substrate, by forming semiconductor layers, insulating layers, and conductive layers in predetermined patterns on the target substrate.

2. Description of the Related Art

A semiconductor device with a multi-layered interconnection structure is manufactured by repeating film-formation and pattern-etching on the surface of a semiconductor wafer, such as a silicon substrate. For example, the connecting portion between a silicon substrate and an interconnection layer disposed thereabove, or the connecting portion between upper and lower interconnection layers is provided with a barrier layer to prevent separation of an underlying layer or to prevent materials of laminated layers from causing counter diffusion relative to each other. For example, a TiN film formed by thermal CVD is used as a barrier layer of this kind. There is a case where a thin Ti film is formed by plasma CVD as an underlying film below the TiN film, and a case where no Ti film is formed as the underlying film.

FIG. 11 is a schematic diagram showing a conventional CVD apparatus for forming a barrier layer. The apparatus has a vacuum process chamber 1 made of, e.g., aluminum. An exhaust port 11 is formed in the bottom of the process chamber 1. A worktable 13 for placing a semiconductor wafer W horizontally thereon is disposed in the process chamber 1. The worktable 13 is made of, e.g., aluminum nitride, and has a heater 12 built therein. A showerhead 15 for supplying process gases is disposed to face the worktable 13. The showerhead 15 is provided with a number of gas delivery holes 14 formed in a portion that faces a wafer W placed on the worktable 13. During film-formation, the heater 12 heats a wafer W placed on the worktable 13, while the showerhead 15 supplies TiCl₄ and NH₃ as process gases. At this time, a reaction is caused in accordance with the following formula (1), so that a thin TiN film is formed over the entire surface of the wafer W.
6TiCl₄+8NH₃→6TiN+24HCl+N₂ (1)

When such a film-formation process is repeatedly performed on a plurality of wafers W, TiN is deposited on a wall or the like in the vacuum process chamber 1. For example, as shown in FIG. 12, a deposited substance 16 gradually accumulates on a portion particularly around the worktable 13, which has a high temperature. As a consequence, the surface of the worktable 13 changes the thermal emissivity; which brings about a difference in the surface temperature of the worktable 13 even at the same set temperature, thereby lowering the uniformity of film thickness between wafers. In order to solve this problem, for example, a step called pre-coating process of forming a TiN film on the entire surface (the top surface, bottom surface, and side surface) of the worktable 13 is performed prior to a film-formation process performed on a wafer W. It has been found that, where the TiN film (pre-coat) formed by the pre-coating process has a thickness of, e.g., 0.5 μm or more, it can prevent the problem described above. This pre-coat also prevents the wafer W from being contaminated by metallic contaminants, such as an aluminum-based material that forms the process chamber 1, and a ceramic-based material that forms the worktable 13, e.g., Al in AlN.

Conventionally, a pre-coating step is performed, as follows. Specifically, at first, the interior of the vacuum process chamber 1 is vacuum-exhausted, while the worktable is heated to a temperature of 600 to 700° C. After the temperature of the worktable 13 becomes stable, the pressure in the vacuum process chamber 1 is set at 40 Pa (0.3 Torr). Then, TiCl₄ gas and NH₃ gas are supplied together as process gases into the vacuum process chamber 1, after their flow rates are stabilized by pre-flow. The flow rate of TiCl₄ gas is set at, e.g., about 30 to 50 sccm, and the flow rate of NH₃ gas at, e.g., about 400 sccm. The two process gases are supplied for a time period of, e.g., about 15 to 20 minutes. Then, in order to perform a post-nitride process, the supply of TiCl₄ gas is stopped and only NH₃ gas is supplied at a flow rate of about 1000 sccm, while the interior of the vacuum process chamber 1 is vacuum-exhausted, for a predetermined time period of, e.g., several tens of seconds. By doing so, a TiN film (pre-coat) having a thickness of, e.g., about 0.5 to 2.0 μm is formed on the surface of the worktable 13. Then, a wafer W is placed on the pre-coated worktable 13, and a film-formation process is performed so that a Ti film 18 and a TiN film 19 are formed on the surface of the wafer W (see FIG. 13), for example.

However, in the film-formation process of a TiN film described above, chlorides are dissociated from TiCl₄ gas or produced as by-products in the pre-coating step, and react with metals of the vacuum process chamber 1, thereby producing metal chlorides. The metal chlorides evaporate during the film-formation step, and are taken into a film formed on the wafer W. If an unexpected metal enters the film, the electrical properties of devices to be formed are affected, thereby lowering the yield. Accordingly, the degree of metal contamination has to be controlled, to be as low as possible. However, the thinner the film of a device is, the stricter the permissible level of metal contamination becomes.

### BRIEF SUMMARY OF THE INVENTION

An object of the present invention is to provide a film-formation method for a semiconductor process, which can reduce the total amount of contaminants, such as metal, in a main film to be formed on a target substrate after a pre-coating process is performed on a worktable in a process chamber.

According to a first aspect of the present invention, there is provided a film-formation method for a semiconductor process to form a film containing a metal element on a target substrate, which is placed on a worktable in an airtight process chamber, the method comprising:
(a) pre-coating of covering the worktable with a pre-coat before loading the target substrate into the process chamber, the pre-coating comprising
a first step of supplying a first process gas including a source gas containing the metal element into the process chamber, while heating the worktable and exhausting the process chamber, thereby forming a segment film containing the metal element on the worktable, and
a second step of supplying a second process gas including no source gas containing a metal element into the process chamber, while heating the worktable and exhausting the process chamber, thereby exhausting and removing, from the process chamber, a byproduct produced in the first step other than a component forming the segment film,
wherein the first and second steps are repeated a plurality of times, thereby laminating a plurality of segment films to form the pre-coat; and
(b) film formation, after the pre-coating, of loading the target substrate into the process chamber, and forming a main film on the target substrate, the film formation comprising
a step of loading the target substrate into the process chamber and placing the target substrate on the worktable, and
a step of supplying the first and second process gases into the process chamber, while heating the worktable and exhausting the process chamber, thereby forming the main film containing the metal element on the target substrate.

According to a second aspect of the present invention, there is provided a CVD method of forming a film containing a metal element on a target substrate, which is placed on a worktable in an airtight process chamber, by supplying a first process gas containing the metal element and a second process gas that assists decomposition of the first process gas into the process chamber, the method comprising:
(a) pre-coating of covering the worktable with a pre-coat before loading the target substrate into the process chamber, the pre-coating comprising
a first step of supplying the first and second process gases into the process chamber, while heating the worktable and exhausting the process chamber, thereby forming a segment film containing the metal element on the worktable, and
a second step of stopping the first process gas and supplying the second process gas into the process chamber, while heating the worktable and exhausting the process chamber, thereby producing a byproduct by reaction of the second process gas with an intermediate produced by decomposition or reaction of the first process gas, and exhausting and removing the byproduct from the process chamber,
wherein the first and second steps are repeated a plurality of times, thereby laminating a plurality of segment films to form the pre-coat, and
the first and second steps employ substantially common process temperature and process pressure, and the byproduct sublimes at the process temperature and process pressure; and
(b) film formation, after the pre-coating, of loading the target substrate into the process chamber, and forming a main film on the target substrate, the film formation comprising
a step of loading the target substrate into the process chamber and placing the target substrate on the worktable, and
a step of supplying the first and second process gases into the process chamber, while heating the worktable and exhausting the process chamber, thereby forming the main film containing the metal element on the target substrate.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a sectional elevation view showing a CVD apparatus according to a first embodiment of the present invention;

FIGS. 2A to 2C are views showing steps of a film-formation method according to the first embodiment in order:

FIG. 3 is a diagram showing time-series control on gas supply/stop and pressure in a pre-coating process used in the film-formation method according to the first embodiment;

FIG. 4 is a diagram showing time-series control on gas supply/stop and pressure in a pre-coating process used in a film-formation method according to a modification of the first embodiment;

FIG. 5 is a graph showing experimental results about the film-formation method according to the first embodiment;

FIG. 6 is a sectional elevation view showing a CVD apparatus according to a second embodiment of the present invention;

FIG. 7 is a diagram showing process conditions of the steps of a pre-coating process used in a film-formation method according to the second embodiment;

FIG. 8 is a graph showing the relationship between the number of repetitions of a pre-coating sequence and Fe concentration in the film-formation method according to the second embodiment;

FIG. 9 is a diagram showing process conditions of the steps of a purging operation after idling (long-term stoppage);

FIG. 10 is a graph showing experimental results about the purging operation shown in FIG. 9;

FIG. 11 is a schematic diagram showing a conventional CVD apparatus;

FIG. 12 is a view for explaining problems of prior art;

FIG. 13 is a view for explaining problems of prior art; and

FIG. 14 is a block diagram schematically showing the structure of a control section.

### DETAILED DESCRIPTION OF THE INVENTION

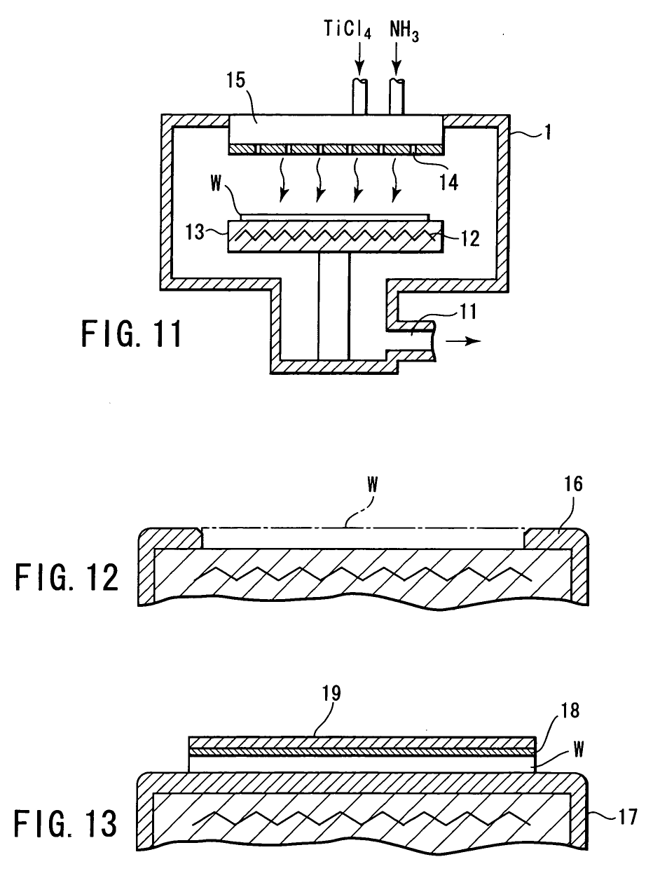

In the process of developing the present invention, the inventors studied problems of conventional film-formation methods performed in the CVD apparatus shown in FIG. 11. As a result, the inventors have arrived at the findings given below.

In a film-formation process of a TiN film, since the inner surface of the process chamber 1 and the surface of the showerhead 15 have lower temperatures than the worktable 13, no or hardly any TiN film is deposited thereon. However, a film may be deposited on the showerhead 15, where the distance between the showerhead 15 and worktable 13 is small. In a film-formation process of a TiN film, TiCl₄ gas or a mixture gas of TiCl₄ gas and NH₃ gas is supplied for a time period as long as, e.g., 15 to 20 minutes. In this case, hydrogen chloride (HCl) is produced due to thermal decomposition of TiCl₄ gas, or reaction between TiCl₄ gas and NH₃ gas. HCl then reacts with the surface portion of metal components of the process chamber 1 or the like, thereby producing a lot of metal chlorides. When a film-formation process is performed on a wafer W, the metal chlorides disperse and are taken into a thin film formed on the wafer W; which is one of the causes behind the rise in metal contaminants.

There are processes other than TiN film formation, which also suffer this problem, i.e., wherein a metal compound is produced during a pre-coating step, and thus a metal contaminant is taken into a thin film formed on a wafer W. For example, where a Ta₂O₅ film is formed by the reaction of PET (pentoethoxytantalum) with O₂ gas, a pre-coat is formed on the surface of a worktable. In this case, metal chlorides stable in the process chamber react with a process gas used in a pre-coating step, and produce unstable substances, which disperse in the process chamber. The metal chlorides are believed to have been produced due to the reaction of ClF₃ gas used in a cleaning step with the surface portion of metal components of the process chamber 1 or the like.

Embodiments of the present invention achieved on the basis of the findings given above will now be described with reference to the accompanying drawings. In the following description, the constituent elements having substantially the same function and arrangement are denoted by the same reference numerals, and a repetitive description will be made only when necessary.

### First Embodiment

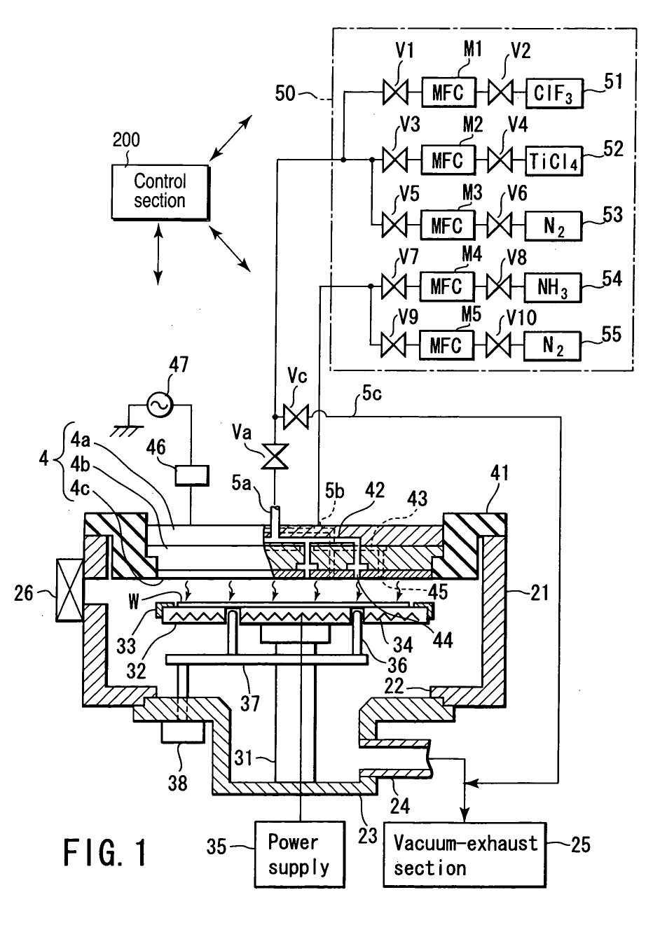

FIG. 1 is a schematic diagram showing a CVD apparatus according to a first embodiment of the present invention. The apparatus includes a cylindrical vacuum process chamber 1 made of, e.g., aluminum. The vacuum process chamber 21 has a recess at the center of the bottom to form an exhaust pit 23. A side surface of the exhaust pit 23 is connected through an exhaust line 24 to a vacuum-exhaust section 25 for keeping the interior of the process chamber 21 at a predetermined vacuum pressure. The process chamber 21 is provided with a gate valve 26 at a sidewall, for transferring a wafer W therethrough.

A worktable (susceptor) 32 is disposed in the process chamber 21. The worktable 32 is formed of a circular plate, whose bottom is supported by a strut 31 extending upward from the bottom of the exhaust pit 23. The worktable 32 is made of a ceramic material, such as aluminum nitride (AlN). The top surface of the worktable 32 is set to be slightly larger than a target substrate or wafer W, and to place the wafer W substantially horizontally thereon. A guide ring 33 made of, e.g., alumina (Al₂O₃) is disposed on the periphery of the worktable 32, for guiding a wafer W and covering the transit portion of the worktable 32 from the top surface to the side surface.

A heater 34 formed of, e.g., a resistance heating body is built in the worktable 32. The heater 34 is temperature-controlled by, e.g., a power supply 35 disposed outside the process chamber 21 in accordance with intended purpose. Thus, the heater 34 uniformly heats the surface of a wafer W in a film-formation step, or heats the worktable surface to a predetermined temperature in a pre-coating step, as described later.

The worktable 32 is provided with lift pins 36 (for example, three pins in practice) for transferring a wafer W relative to a transfer arm (not shown), which enters through the gate valve 26. The lift pins 36 can project from and retreat into the worktable 32. The lift pins 36 are moved up and down by an elevating mechanism 38 through a support member 37 that supports their bottoms.

A showerhead 4 is disposed on the ceiling of the process chamber 21 through an insulating member 41. The showerhead 4 has a post-mix type structure, which prevents two different gases from mixing with each other inside the showerhead 4, while it supplies the gases individually uniformly toward the worktable 32. The showerhead 4 includes three plate parts (upper part 4a, middle part 4b, and lower part 4c) made of, e.g., aluminum or nickel, and arrayed in the vertical direction. A first flow passage 42 connected to a first gas supply line 5a and a second flow passage 43 connected to a second gas supply line 5b are separately formed in the parts 4a, 4b, and 4c. The first and second flow passages 42 and 43 communicate with gas delivery holes 44 and 45 formed in the bottom surface of the lower part 4c through gas diffusion spaces formed between the parts.

The first and second gas supply lines 5a and 5b are fed with respective gases from a gas supply mechanism 50 disposed on the upstream side. The gas supply mechanism 50 includes a cleaning gas supply source 51, a film-formation gas supply source 52, a first carrier gas supply source 53, an ammonia gas supply source 54, and a second carrier gas supply source 55. The cleaning gas supply source 51 supplies a cleaning gas, such as ClF₃ gas. The film-formation gas supply source 52 supplies titanium tetrachloride (TiCl₄) gas, which is a process gas containing Ti used as a film-formation component. The first carrier gas supply source 53 supplies a carrier gas, such as an inactive gas, e.g., nitrogen (N₂) gas, used for supplying TiCl₄ gas. The ammonia gas supply source 54 supplies ammonia (NH₃) gas. The second carrier gas supply source 55 supplies a carrier gas, such as N₂ gas, used for supplying NH₃ gas.

The lines of the gas supply mechanism 50 are provided with valves V1 to V10 and mass-flow controllers M1 to M5. The first gas supply line 5a has a branch to a bypass line 5c for directly exhausting gas to the exhaust line 24, bypassing the process chamber 21. Valves Va and Vc are switched for gas to flow through the process chamber 21 or the bypass line 5c.

As described later, NH₃ gas is used as “a process gas for forming a segment film” and also as “a process gas for removing a metal chloride” in a pre-coating process. TiCl₄ gas corresponds to “a process gas containing a metal compound” as well as “a process gas or compound containing a metal and a halogen element.”

The showerhead 4 is connected to an RF (Radio Frequency) power supply 47 through a matching device 46. The RF power supply 47 is used to turn a film-formation gas, supplied to a wafer W, into plasma during a film-formation process, thereby accelerating a film-formation reaction. A control section 200, such as a computer, is arranged to control adjustment on the members constituting the film-formation apparatus, such as drive of the elevating mechanism 38, output of the power supply 35, the exhaust rate of the vacuum-exhaust section 25, and the gas supply/stop and flow rate of the gas supply mechanism 50. This control is performed in accordance with a recipe prepared in the control section in advance.

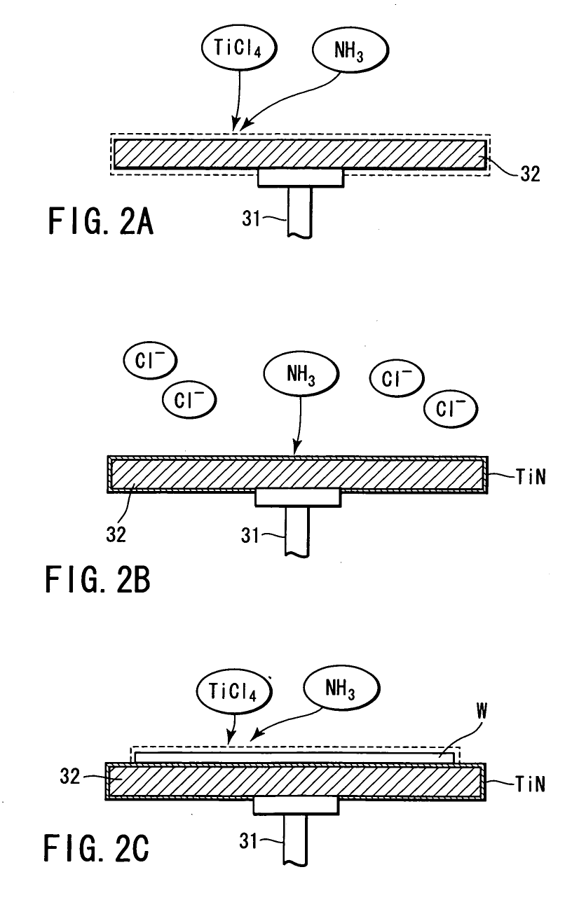

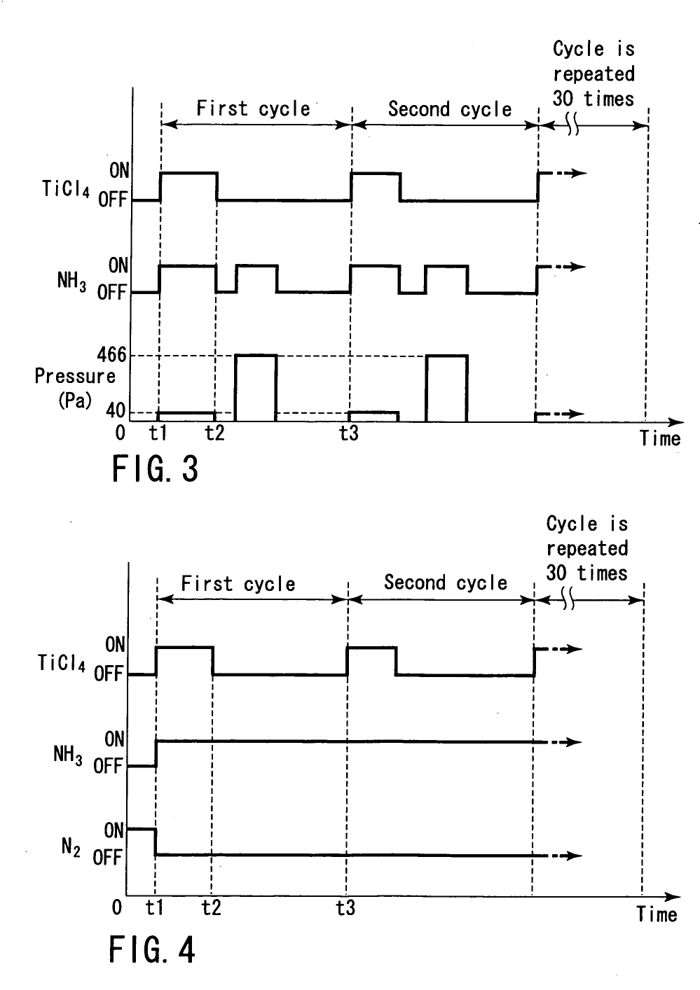

Next, with reference to FIGS. 2A to 2C and 3, an explanation will be given of a film-formation method using the apparatus described above, in an example where a titanium nitride (TiN) film is formed on the surface of a wafer W. In FIGS. 2A to 2C, the guide ring 33 is not shown, for the sake of convenience.

Prior to a film-formation step on the wafer W, a pre-coating step is performed, using TiCl₄ gas and NH₃ gas, to form a thin TiN film on the surface of the worktable 32. Since the pre-coating step is used to form, e.g., a TiN film over the entire surface of the worktable 32, it is performed in a state where no wafer W is present in the process chamber 21.

Specifically, the interior of the process chamber 21 is first vacuum-exhausted by the vacuum-exhaust section 25 with the pressure control valve fully opened. An inactive gas, such as N₂ gas, is supplied at a flow rate of, e.g., about 500 sccm from the first and second carrier gas supply sources 53 and 55. The worktable 32 is heated by the heater 34 to a predetermined temperature of, e.g., about 600 to 700° C. N₂ gas used as a sheath gas is supplied at a flow rate of, e.g., about 300 sccm from a gas supply mechanism (not shown) into the strut 31 of the worktable 32. The sheath gas is used to set the interior of the strut 31 at a positive pressure, so as to prevent a process gas from coming into the strut 31, in which the lead lines of the heater 34 embedded in the worktable 32 are disposed, thereby preventing corrosion of the lines and terminals in the strut 31. The sheath gas is kept supplied continuously from this time point.

FIG. 3 is a diagram showing time-series control on gas supply/stop and pressure in a pre-coating process used in the film-formation method according to the first embodiment.

In the step described above, when the temperature inside the process chamber 21 becomes stable, supply of two process gases is turned on at a time point t1, i.e., the first gas supply line 5a starts supplying TiCl₄ gas and N₂ gas, and the second gas supply line 5b starts supplying NH₃ gas. The process chamber 21 is kept vacuum-exhausted, while these process gases are supplied. In order to stabilize the gas flow rate of TiCl₄ gas, pre-flow thereof is performed such that it flows not through the process chamber 21 but through the bypass line 5c to the exhaust line, for, e.g. 1 to 60 seconds, such as 10 seconds as in this example, from the time point t1. Then, the valves Va and Vb are switched to change the gas flow passages of the TiCl₄ gas, and the gas is supplied into the process chamber 21 until a time point t2, e.g., for 5 to 90 seconds, such as 30 seconds as in this example. On the other hand, the NH₃ gas is continuously supplied into the process chamber 21 between the time points t1 and t2, e.g., for 10 to 120 seconds, such as 40 seconds as in this example. Accordingly, the process chamber 21 is supplied with the TiCl₄ gas and NH₃ gas together, e.g., for 5 to 120 seconds, and preferably 10 to 60 seconds.

As shown in FIG. 2A, the TiCl₄ gas and NH₃ gas thus supplied cause a first TiN pre-coat thin film (segment film) to be formed over the entire surface of the worktable 32 (first step: segment film forming step). From the time point t1 to the time point t2, the interior of the process chamber 21 is kept at a pressure of, e.g., 13.3 to 133.3 Pa (0.1 to 1.0 Torr). The TiCl₄ gas is set at a flow rate of, e.g., about 5 to 100 sccm, and preferably of about 30 to 80 sccm. The NH₃ gas is set at a flow rate of, e.g., about 50 to 1000 sccm, and preferably of 200 to 800 sccm. The process temperature is set to fall in a range of, e.g., about 300 to 700° C., and preferably of 400 to 600° C.

In this step, the TiCl₄ gas and NH₃ gas react with each other in accordance with the formula (1) described above, and a TiN film is formed on the surface of the worktable 32. On the other hand, the inner wall of the process chamber 21 and the surface of the showerhead 4 have temperatures lower than the process temperature. Accordingly, the reaction of the formula (1) essentially does not occur on these members, while the two process gases are exhausted in gaseous states therefrom, thereby depositing no TiN film. Then, at the time point t2, the supply of TiCl₄ gas and NH₃ gas is stopped, and the interior of the process chamber 21 is vacuum-exhausted. During this time, N₂ gas, for example, may be supplied.

Then, as shown in FIG. 2B, while the TiCl₄ gas remains stopped, the NH₃ gas is supplied at a flow rate of, e.g., 500 to 2000 sccm for, e.g., 1 to 60 seconds, and preferably 5 to 20 seconds, such as 30 seconds as in this example, (second step: metal chloride removing step). For details, N₂ gas is supplied as a carrier gas, in addition to the NH₃ gas. During this time, the process chamber 21 is kept vacuum-exhausted. By doing so, the interior of the process chamber 21 is set at a pressure of, e.g., 133.3 to 666.5 Pa (1 to 5 Torr). Then, the supply of NH₃ gas is stopped, and the interior of the process chamber 21 is vacuum-exhausted, so as to remove remaining NH₃ gas in the process chamber 21. During this time, N₂ gas, for example, may be supplied. At a time point t3, one cycle finishes.

This step cycle between the time points t1 and t3 is repeated a plurality of times, such as 10 cycles or more, and preferably 30 cycles or more. As a consequence, segment films are laminated to form a pre-coat. The number of cycles is suitably adjusted, on the basis of the thickness of a thin film formed by one cycle.

As described above, only the NH₃ gas is supplied between the segment film forming steps in the pre-coating process, so that chloride components produced in the segment film forming steps are removed from the process chamber 21. It is thought that chlorine components in the process chamber 21 are removed in accordance with a mechanism, as follows. Specifically, in the reaction of the formula (1), non-reacted TiClx's (x is an arbitrary natural number) are dissociated from TiCl₄, and chlorides are produced as byproducts. These substances react with metal portions inside the process chamber and thereby produce metal chlorides. The metal chlorides are reduced by NH₃ gas, and HCl produced in this reduction reaction then reacts with NH₃, thereby producing ammonium chloride (NH₄Cl). Byproducts, such as HCl and NH₄Cl, and non-reacted substances, such as TiClx, sublime at the process temperature described above, and are exhausted without being deposited on the inner wall of the process chamber 21 or the like.

In accordance with the steps described above, pre-coating is applied to (by a so-called cycle pre-coating process) over the entire surface of the worktable 32, and a TiN film having a film thickness of, e.g., about 0.7 μm is thereby formed on the worktable 32. Thereafter, the temperature of the worktable 32 is kept at about 400 to 700° C. by the heater 34, and the interior of the process chamber 21 is vacuum-exhausted. With these conditions, the gate valve 26 is opened, and a wafer W is loaded into the process chamber 21 by a transfer arm (not shown). Then, the transfer arm cooperates with the lift pins 36 to place the wafer W onto the top surface (on the pre-coat) of the worktable 32. Then, the gate valve 26 is closed to prepare for a film-formation process (film-formation step) on the wafer W.

In the film-formation step, as shown in FIG. 2C, TiCl₄ gas and NH₃ gas are supplied onto the wafer W placed on the worktable 32, while the interior of the process chamber 21 is vacuum-exhausted. At this time, the process temperature is set at about 400 to 700° C., and the process pressure at about 100 to 1000 Pa. This process continues until a TiN film having a predetermined thickness is formed. More specifically, for example, the process temperature is set at 680° C., the process pressure at 667 Pa. The film-formation time is suitably set in accordance with a desired film thickness, because the film thickness is in proportion to the film-formation time. If necessary, an RF power may be applied from the RF power supply 47, at a frequency of 450 kHz to 60 MHz, and preferably of 450 kHz to 13.56 MHz, and at a power of 200 to 1000 W, and preferably of 200 to 500 W, to turn the process gas into plasma to accelerate the reaction during the film-formation. In this case, the process temperature is set at about 300 to 700° C., and preferably at 400 to 600° C.

After formation of a TiN film on the surface of the wafer W is completed, the supply of both process gases, TiCl₄ and NH₃, is stopped, and the interior of the process chamber 21 is purged for, e.g., 10 seconds. Then, NH₃ gas is supplied along with N₂ gas used as a carrier gas into the process chamber 21 to perform a post-nitride process on the TiN film surface on the wafer W. The same steps described above are repeated to perform the film-formation process for a predetermined number of wafers W.

After a lot of or a predetermined number of wafers W are processed, cleaning is performed to remove unnecessary products deposited inside the process chamber 21. In the cleaning, the temperature of the worktable 32 is set at, e.g., 200° C., and ClF₃ gas is supplied into the process chamber 21. By doing so, the pre-coat formed on the surface of the worktable 32 is also removed. Thereafter, when the film-formation step is performed for a predetermined number of other wafers W, the steps starting from the pre-coating step are repeated again, as described above.

According to this embodiment, as will be evident in results described later, it is possible to remarkably reduce metals, which are used for components of the process chamber 21 or showerhead 4, to be taken in a TiN film formed on a wafer W.

According to a conventional pre-coating process, TiCl₄ gas and NH₃ gas used as process gases are made to flow continuously for a long time. As a consequence, non-reacted TiClx's produced by decomposition of TiCl₄, and chlorides, such as HCl and NH₄Cl, produced as byproducts are present within the process chamber 21 and in the body of a pre-coat. It is thought that the chlorides react with metal portions inside the process chamber 21 and thereby produce metal chlorides, which are then taken into a film formed on a wafer W during a film-formation step.

In contrast, according to this embodiment, TiCl₄ gas and NH₃ gas are supplied into the process chamber 21 to form a thin pre-coat (segment film) on the worktable 32, and then NH₃ gas is supplied to remove metal chlorides by changing them to gases, such as HCl or NH₄Cl. These two steps are combined to form one cycle, which is repeated several tens of times to form a pre-coat having a predetermined film thickness. As a consequence, it is possible to reduce the quantity of metal chlorides produced in the process chamber 21, and to thereby reduce the quantity of metals mixed in a film formed on a wafer W.

In other words, according to this embodiment, a pre-coat is formed not by performing film-formation continuously for a long time, but by repeating film-formation of a segment film and removal of chlorides (purge or exhaust), both of which are steps of short periods of time. As a consequence, it is possible to reduce the quantity of chlorides produced in each step, and to thereby reduce the quantity of chlorides remaining in the process chamber 21.

An experiment was conducted to compare methods according to a conventional technique and the present invention, in terms of the concentration of chlorine present as chlorides in the process chamber 21 when a pre-coating process finished. The results of this experiment revealed that the conventional method showed a chlorine concentration as high as about 2 to 3 at %. On the other hand, this embodiment method showed a reduced chlorine concentration of about 0.1 at %. Accordingly, it has been confirmed that this embodiment can reduce the quantity of metal chlorides produced.

In the pre-coating process, NH₃ gas does not have to be intermittently supplied. Furthermore, in the pre-coating process, N₂ gas does not have to be supplied from the time point t1 of the embodiment described above. FIG. 4 is a diagram showing an example of this case, in the same manner as FIG. 3. No explanation will be given of conditions, such as flow rates and pressures, because they are the same as those in the embodiment described above.

First, purging is performed with N₂ gas until a time point t1 when the temperature in the process chamber 21 becomes stable. At the time point t1, supply of TiCl₄ gas and NH₃ gas is turned on, and supply of N₂ gas is turned off. From the time point t1, only TiCl₄ gas is intermittently supplied, while the supply of NH₃ gas is maintained, and N₂ gas is not supplied. This cycle is repeated a predetermined number of times, e.g., 30 times. Also according to this method, chlorides within the process chamber and in the body of a film are removed by NH₃ gas from a time point t2 to a time point t3. Since pre-coating and film-formation processes are repeated, it is possible to attain the same effects as in the case described above.

In the method explained with reference to FIG. 3 or 4, a TiN film is formed in both of the pre-coating and film-formation processes. Alternatively, a Ti film may be formed in both of the pre-coating process and the film-formation process on a wafer W. Where a Ti film is formed, for example, TiCl₄ gas and hydrogen (H₂) gas are used as process gases, and, in addition, argon (Ar) gas is used as a gas to be plasma. More specifically, the three gases are supplied into the process chamber 21 at a film-formation temperature of 700° C. and a pressure of 133 Pa (1 Torr). An RF power is applied to the showerhead 4 to turn Ar gas into plasma, so as to accelerate the reduction reaction between TiCl₄ gas and H₂ gas. As a consequence, a Ti film is formed on the surface of the worktable 32 or wafer W. At this time, for example, the flow rate of TiCl₄ gas is set at about 1 to 200 sccm, the flow rate of H₂ gas at about 1 to 2 liter/min, and the flow rate of Ar gas at about 1 liter/min.

As described above, a Ti film can be used for both of the pre-coating of the worktable 32 and film-formation on a wafer W. Accordingly, this embodiment may be applied to, for example, four patterns, i.e., TiN film pre-coating+TiN film formation, Ti film pre-coating+TiN film formation, TiN film pre-coating+Ti film formation, Ti film pre-coating+Ti film formation. In TiN film formation, a Ti film may be formed as an underlying film before a TiN film is formed (including pre-coating).

In any of the cases described above, NH₃ gas is used as a reaction gas for removing chlorides, and steps the same as those of the method explained with reference to FIG. 3 or 4 are repeated a plurality of times, thereby attaining the same effect as in the explained method. The gas used for removing metal chlorides is not limited to NH₃ gas, but may be a gas that can produce ammonium halide. For example, a gas containing nitrogen and hydrogen, such as a hydrazine gas, e.g., N₂H₂, may be used. Alternatively, N₂ gas, H₂ gas, and NH₃ gas may be suitably mixed for supply, and turned into plasma. In any of the cases, it is possible to attain the same effect as in the method explained with reference to FIG. 3 or 4.

In order to confirm effects of this embodiment, an experiment was conducted to compare the conventional method explained in the Background Art and a present example method according to this embodiment. In this experiment, the process temperature was set at 680° C., the process pressure at 40 Pa, the flow rate of TiCl₄ gas at about 30 to 50 sccm, the flow rate of NH₃ gas at about 400 sccm. In the conventional method, process gases were kept flowing for 10 to 15 minutes to perform a film-formation process on a wafer (an alternative to a pre-coating process). In the present example method, the cycle described above was repeated a plurality of times to perform a film-formation process on a wafer (an alternative to a pre-coating process). In either method, the target film thickness was set at 0.7 μm.

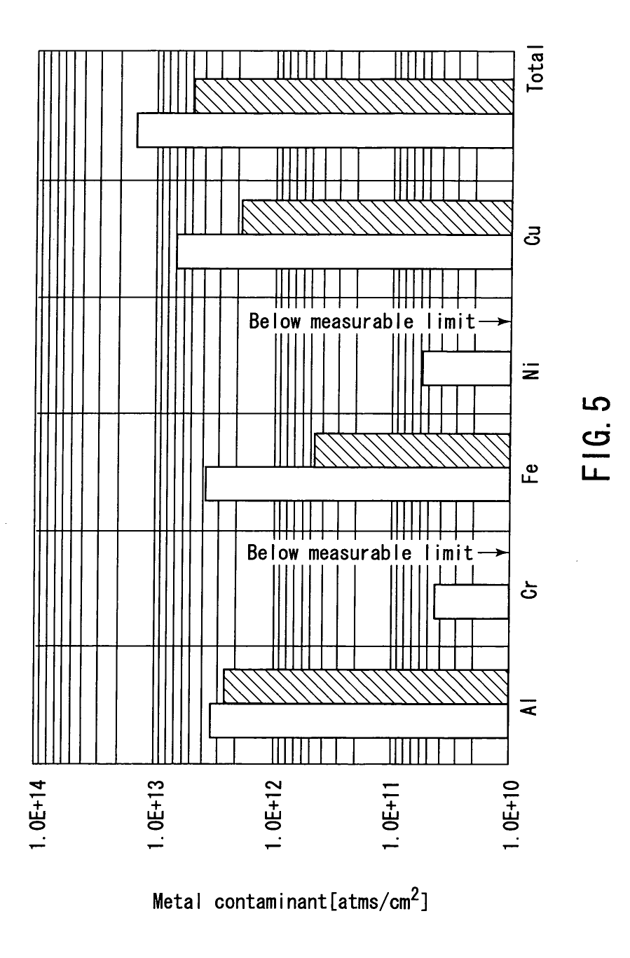

FIG. 5 is a graph showing results of comparison between the two methods, in terms of the measured quantity of metal contaminants (the number of atoms per unit area) in a TiN film formed by the methods. In FIG. 5, the outline bar denotes the conventional method, and the hatched bar denotes the present example method. As shown in FIG. 5, the present example method contained less metal contaminants than the conventional method, for all the items of Al, Cr, Fe, Ni, Cu, and total. Accordingly, it has been found that the film-formation method according this embodiment reduces metal contamination. It is presumed that this effect correlates to the fact described above that a pre-coating process according to this embodiment reduces the quantity of chlorides within the process chamber 21.

This embodiment may be applied to a case where a thin film other than a Ti or TiN film is formed by a vapor phase reaction, using a metal compound gas that contains a film-formation component metal and a halogen element. For example, it may be applied to a case where a W (tungsten) film is formed, using WF₆ (tungsten hexafluoride) gas and H₂ gas (SiH₄ gas may be used instead). It may be also applied to a case where a WSi₂ (tungsten silicide) film is formed, using WF₆ gas and SiH₂Cl₂ (dichlorosilane) gas. It may be also applied to a case where a Ta film is formed, using TaBr₃ or TaCl₃ gas and H₂ gas, or a TaN film is formed, using TaBr₃ or TaCl₃ gas and NH₃ or NH₃ and H₂ gas.

This embodiment may be also applied to a case where a pre-coat is formed, using an organic metal gas other than a metal compound gas containing a metal and a halogen element. For example, where a Ta₂O₅ (tantalum oxide) film is formed on a wafer, using PET (pentoethoxytantalum: Ta(OC₂H₅)₅) and O₂ gas, a pre-coat is formed, using PET and O₂ gas. In this case, non-reacted carbon compounds dissociated from PET and byproducts containing C (carbon) come into the bodies of a process chamber and a thin film (pre-coat film), and then C derived therefrom is taken, although slightly, into the surface of the wafer W during the film-formation process. Accordingly, in the pre-coating process, a cycle including a step of supplying PET and O₂ gas together and a step of then supplying only O₂ gas is repeated, as in the sequence shown in FIG. 3. As a consequence, O₂ gas, in the step of supplying only O₂ gas, reacts with C of carbon compounds and byproducts present in the process chamber, and thereby producing carbon dioxide to be removed.

### Second Embodiment

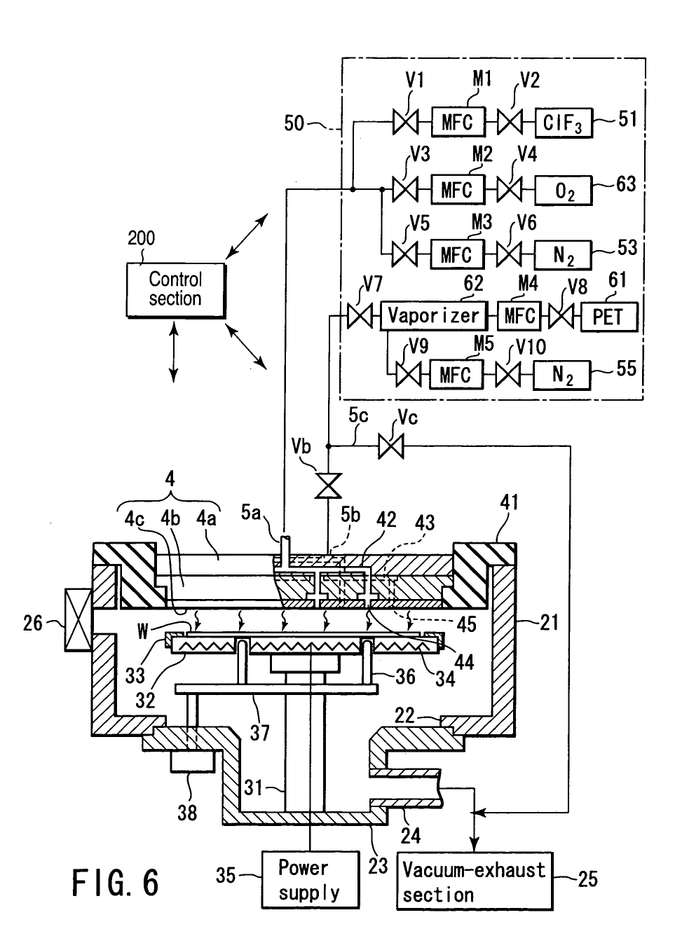

FIG. 6 is a schematic diagram showing a CVD apparatus according to a second embodiment of the present invention. This apparatus is configured to form a Ta₂O₅ film on a wafer. The following explanation is directed to a method of reducing metal contamination on a wafer, in a case where a pre-coat is first formed on a worktable, using PET, which is a source gas containing a metal element, and O₂ gas, and a Ta₂O₅ film is then formed on the wafer. This method repeats a series of steps a plurality of times, i.e., a step of supplying PET and O₂ gas together into a process chamber to form a pre-coat, a step of then purging the interior of the process chamber by an inactive gas, such as N₂ (nitrogen gas), and a step of then vacuum-exhausting the interior of the process chamber.

In the film-formation apparatus shown in FIG. 6, since PET is in liquid phase at normal temperatures, PET is supplied in liquid phase from a supply source 61 and vaporized by a vaporizer 62, and then fed into a process chamber 21. O₂ gas is supplied from a supply source 63. A bypass line 5c having a downstream side connected to an exhaust line 24 is provided to bypass the vacuum process chamber 21. Valves Va and Vc are switched between a state where PET gas and N₂ gas flowing through a second gas supply line 5b are supplied into the process chamber 21, and a state where they are exhausted while bypassing the process chamber 21.

Since a Ta₂O₅ film is formed by thermal decomposition reaction of PET, the matching device 46 and RF power supply 47 for plasma generation shown in FIG. 1 are omitted here. As regards the other portions, the same reference numerals as in FIG. 1 are used to denote the same portions, and thus no explanation will be given of the other portions to avoid repetitive description.

In order to heat a target substrate, a conventional lamp heating structure may be employed in place of a resistance heating body built in a worktable. In this case, a worktable is heated by a lamp-heating source disposed below the worktable. Where lamp heating is employed, the worktable is preferably formed of a SiC (silicon carbide) member having a thickness of, e.g., about 7 mm.

Next, an explanation will be given of a film-formation method according to the second embodiment. FIG. 7 is a diagram showing gas flow rates and so forth in the steps of a pre-coating process used in a film-formation method according to the second embodiment. In FIG. 7, “5a:” means a state where gas flows through the first gas supply line 5a, “5b:” means a state where gas flows through the second gas supply line 5b, and “5c:” means a state where gas flows through the bypass line 5c. In the following steps S1 to S5, the process chamber 21 is kept vacuum-exhausted.

In the step S, the worktable is heated to a temperature of 445° C., and N₂ gas is supplied through the first gas supply line 5a into the process chamber 21, to perform a pre-coating step. Then, in the step S2, the flow rate of N₂ gas is reduced from 1000 sccm to 600 sccm, and O₂ gas is supplied into the process chamber 21 at a flow rate of 400 sccm. In the steps S1 and S2, PET gas and N₂ gas are supplied through the second supply line 5b for pre-flow, and exhausted not through the process chamber 21 but through the bypass line 5c.

In this case, the PET pre-flow in the step S1 is performed at a flow rate controlled with a flowmeter tolerance of 90 mg±15 (10 to 15) mg. On the other hand, the PET pre-flow in the step S2 is performed at a flow rate controlled with a flowmeter tolerance of 90 mg±5 (3 to 10) mg, so that the PET can be stably supplied into the process chamber. For example, in the step S2, the pre-flow of PET is performed once, for a predetermined time period of 20 seconds or more, and preferably of 30 seconds or more.

Thereafter, in a step S3 (segment film formation step), N₂ gas supply through first gas supply line 5a stops, and PET gas and N₂ gas flowing through the second gas supply line 5b for pre-flow are switched and supplied into the process chamber 21. As described above, since pre-flow is performed before film-formation, process gases are supplied at stable flow rates from the beginning of the step S3. Furthermore, since the gas flow rate through the process chamber is kept constant 21 (for example, the total flow rate is set at 1000 sccm) from the step S1 to step S3, the temperatures of the worktable 32 and wafer are prevented from varying due to change in the pressure in the process chamber 21.

The film thickness of a deposited segment film (Ta₂O₅ film) can be adjusted by changing the time period of the step S3, as follows. In this embodiment, where the time period of the step S3 is set at 58 seconds, 71 seconds, 141 seconds, and 281 seconds, the film thickness of a segment film becomes about 5.2 nm, 6.5 nm, 13 nm, and 26 nm, respectively.

In the steps S1 to S3, the interior of the process chamber 21 may be arbitrarily set at a pressure of about 13.3 to 1333 Pa, and preferably of about 39.9 to 667 Pa. The process temperature may be arbitrarily set at a value of about 300 to 800° C., and preferably of about 350 to 500° C.

Then, in a step S4, the supply of PET gas and O₂ gas is stopped and only N₂ gas is supplied to perform purging. Then, in a step S5, the supply of N₂ gas is stopped, i.e., all the gas supplies are stopped, and the interior of the process chamber is vacuum-exhausted. In the step S4, N₂ gas is supplied into the process chamber 21 through at least one of the first and second supply lines 5a and 5b and exhausted to perform purging. One pre-coating sequence for the worktable 32 is finished upon the completion of the steps S1 to S5 described above. Afterward, the cycle of steps S1 to S5 or steps S2 to S5 is repeated a necessary number of times. As a consequence, segment films are laminated, thereby forming a pre-coat. The number of repetitions of the cycle is suitably adjusted in accordance with the thickness of a thin film formed by one cycle.

With the process described above, the worktable 32 is covered with a pre-coat of a Ta₂O₅ film. Thereafter, while a heater 34 maintains the temperature of the worktable 32, the interior of the process chamber 21 is vacuum-exhausted. In this state, a gate valve 26 is opened, and a wafer W is loaded into the process chamber 21 by a transfer arm (not shown). Then, the wafer W is placed on the top surface (on the pre-coat) of the worktable 32 by the transfer arm in cooperation with the lift pins 36. Then, the gate valve 26 is closed to start a film-formation process (film-formation step) on the wafer W.

In the film-formation step, while the interior of the process chamber 21 is vacuum-exhausted, PET and O₂ gas are supplied onto the wafer W placed on the worktable 32. By doing so, a Ta₂O₅ film having a predetermined thickness is formed on the wafer W. This process may employ process conditions the same as those of the step 3 of the pre-coating process.

According to this embodiment, since a film-formation process is performed on a wafer after a pre-coating step, the metal contamination concentration in a thin film formed on the wafer is reduced. An experiment was conducted, as follows: The pre-coating cycle (sequence) shown in FIG. 7 was repeated a predetermined number of times to form a pre-coat on a worktable. The worktable was then used to form a Ta₂O₅ film on a wafer. Then, the metal contamination concentration in the formed thin film was measured.

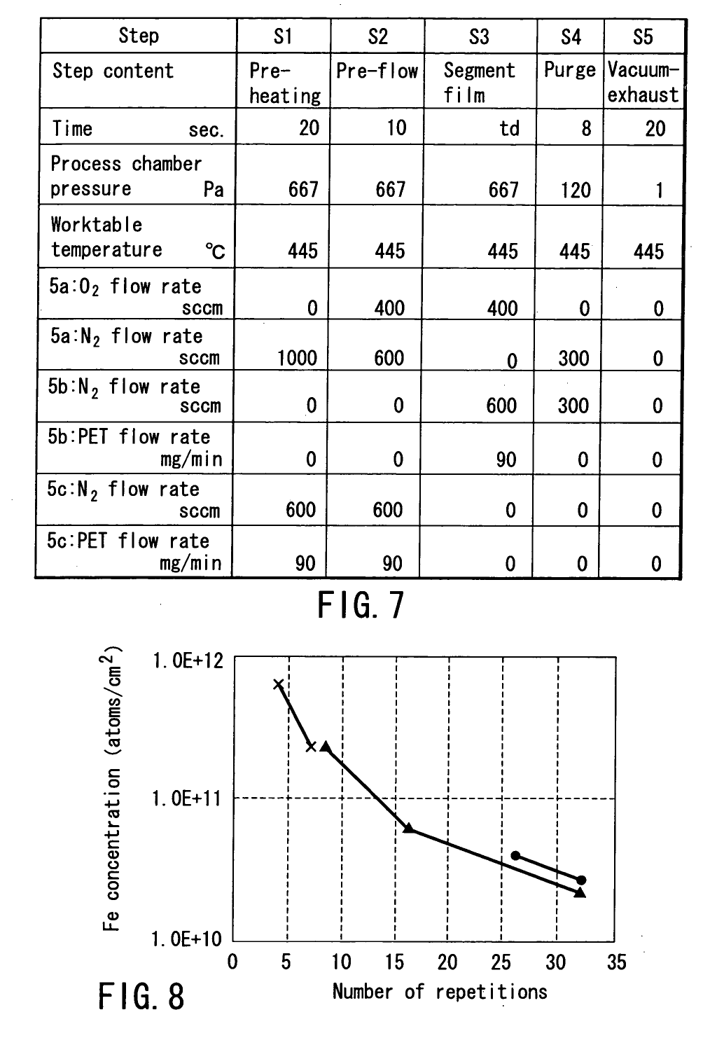

FIG. 8 is a graph showing its experimental results. In FIG. 8, the horizontal axis denotes the number of repetitions of the pre-coating cycle (sequence), and the vertical axis denotes the number of Fe atoms per unit area in the Ta₂O₅ film. The symbols “x” show results where the target film thickness of the pre-coat was set at 90 nm, and the number of repetitions of the pre-coating sequence was set at 4 and 7. The symbols “▴” show results where the target film thickness of the pre-coat was set at 210 nm, and the number of repetitions of the pre-coating sequence was set at 8, 16, and 32. The symbols “●” show results where the target film thickness of the pre-coat was set at about 170 nm, and the number of repetitions of the pre-coating sequence was set at 26 and 32.

For example, in the data shown by “▴”, where the sequence is repeated 8 times, the pre-coat film thickness formed by each sequence is about 26 nm (210 nm/8). Where the sequence is repeated 16 times, the pre-coat film thickness formed by each sequence is about 13 nm (210 nm/16). Where the sequence is repeated 32 times, the pre-coat film thickness formed by each sequence is about 6.5 nm (210 nm/32).

As shown in FIG. 8, the Fe concentration (contaminant quantity) in the thin film strongly correlates to the number of repetitions of the pre-coating sequence, such that it decreases with increase in the number of repetitions. Although FIG. 8 shows only Fe concentration, similar results are also obtained for aluminum and copper.

Semiconductor device design rules (pattern line width) become stricter year by year, and require permissible metal contamination (metal contaminant quantity) to be lower. In the current situation, a criterion of the metal contaminant quantity is set at a level of 1.0×1011 (atoms/cm²). Judging from this, the number of repetitions of the pre-coating sequence is preferably set at 13 or more, and preferably at 15 or more. However, a criterion of the metal contaminant quantity may be changed, depending on the user's request. In this respect, as shown in FIG. 8, it has been confirmed that a distinct effect can be obtained where the number of repetitions of the pre-coating sequence is 4 or more.

As described previously, the pre-coat needs to have a certain thickness to prevent the thermal emissivity from varying, thereby maintaining uniformity in film thickness between wafers (inter-surface uniformity). For Ta₂O₅ films, this certain thickness is about 90 nm. Accordingly, in order to complete a pre-coating process fastest, the thickness of one segment film formed by each pre-coating sequence is set at a value made by dividing 90 nm by the number of repetitions. For example, where the number of repetitions is 4, the segment film thickness is set at about 22.5 nm. Where the number of repetitions is 15, the segment film thickness is set at about 6 nm. However, the thickness of one segment film formed by each pre-coating sequence may be arbitrarily selected.

It is presumed that the following mechanism contributes to the fact that the metal contaminant quantity in a film on a wafer is reduced by repeating the pre-coating sequence a plurality of times. Specifically, a Ta₂O₅ film is formed by thermal decomposition of PET. O₂ gas supplied along with PET is an assist gas, which has some effect on the film quality, reaction rate, and the like of the Ta₂O₅ film, but does not appear in the chemical reaction formula of production of the Ta₂O₅ film. This chemical reaction formula is expressed as follows. At first, PET is thermally decomposed, as in formula (11).
2Ta(OC₂H₅)₅→Ta₂O₅+5C₂H₄+5C₂H₅OH (11)

With progress of the thermal decomposition, C₂H₅OH shown above is decomposed, as in formula (12).
5C₂H₅OH→5C₂H₄+5H₂O (12)

If metal chlorides, such as FeCl₃, are present in the process chamber 21, they react with ethanol shown as an intermediate product in the above formula, and thereby produce ethoxy-compounds, as in formula (13).
FeCl₃+3C₂H₅OH→Fe(OC₂H₅)₃+3HCl (13)

The ethoxy-compounds are readily vaporized by the process temperature in the process chamber 21, and are exhausted. As a consequence, while the pre-coating is performed, it is possible to reduce metal chlorides, which can cause metal contamination during the following film-formation on a wafer. Unlike TiN film pre-coating, Ta₂O₅ film pre-coating does not bring about metal chlorides during the pre-coating process. On the other hand, the interior of the process chamber 21 is periodically cleaned, using a cleaning gas containing a halogen, such as ClF₃ gas. Judging from these facts, it is presumed that the metal chlorides are produced during the cleaning.

Although being vaporized and exhausted, metal ethoxy-compounds are inevitably produced during the pre-coating process, and floats within the process chamber 21 or deposit on the inner wall of the process chamber. Accordingly, as shown in FIG. 7, each pre-coating sequence includes the N₂ purge step S4 of removing non-reacted substances and byproducts containing ethoxy-compounds, following the reaction in the step S3. Furthermore, the step S5 is preferably performed to completely remove remnants after the N₂ purge, thereby further reducing the metal contaminant quantity. However, the step S5 may be omitted, because the interior of the process chamber 21 is kept vacuum-exhausted in the steps S1 to S4. The gas supplied in the step S3 is not limited to N₂ gas, but may be another inactive gas, such as Ar.

It happens that there is a vacant period after wafers are sequentially processed and before the next lot starts being processed. This vacant time state can be called idling. Where a process is resumed after idling, the metal contaminant quantity in a film formed on a wafer occasionally increases. As one of the reasons, it is thought that back diffusion of gas, such as alcohol, occurs from the exhaust system into the process chamber 21. Specifically, the exhaust system of the process chamber 21 is provided with a throttle valve for adjusting pressure, a trap for catching non-reacted substances and byproducts, and a vacuum pump, in this order from the upstream side of the exhaust line 24. Although the interior of the process chamber 21 is purged, using an inactive gas, such as N₂ gas, during idling, alcohol or the like present in byproducts caught by the trap diffuses back into the process chamber 21. As a consequence, ethoxy-compounds can be produced, as shown in the formula (13).

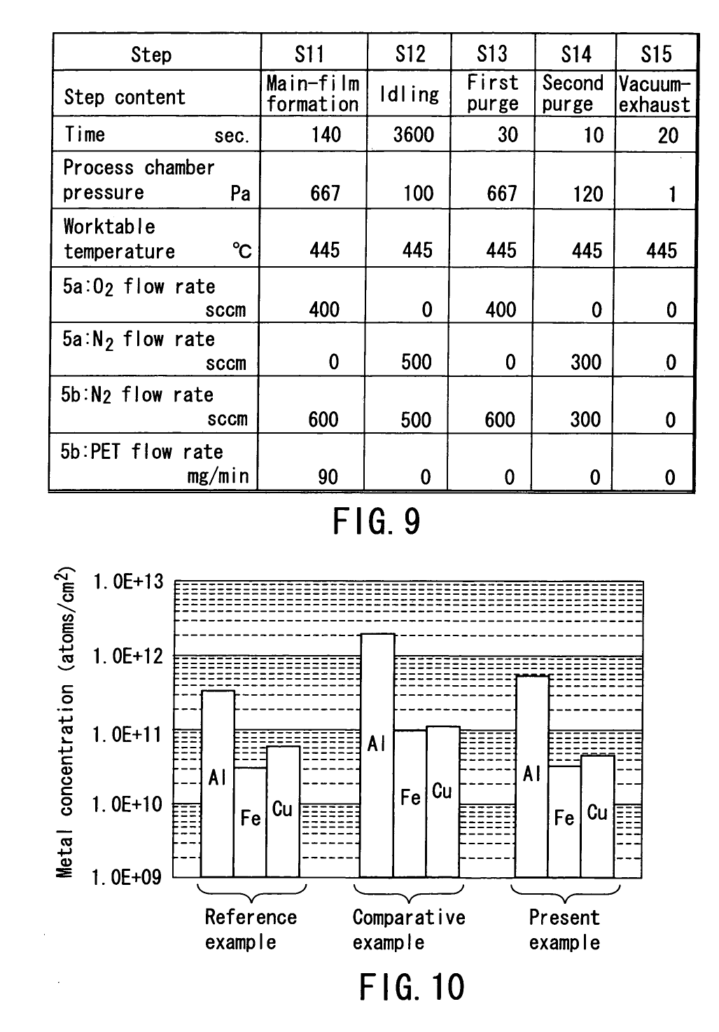

In consideration of this, where a process is resumed after idling, a pre-coating cycle is performed, as described above, thereby reducing the metal contaminant quantity in a film to be formed on a wafer by the process. In this case, it is also effective to repeat purge and vacuum-exhaust in accordance with the timetable shown in FIG. 9. In FIG. 9, “5a:”, “5b:”, and “5c:” have the same meanings as those explained in FIG. 7. In steps S11 to S15 described below, the interior of the process chamber 21 is kept vacuum-exhausted.

The step S11 is a Ta₂O₅ film formation step performed on a wafer immediately before idling. The step S12 is a period of time of the idling (for example, 3,600 seconds, although it varies depending on the situation). In the step S13, O₂ gas and N₂ gas are supplied into the process chamber 21 to perform first purge, as a preparation to start of the next lot process. Then, in the step S14, N₂ gas is supplied into the process chamber 21 at a rate lower than that of the step S13, to perform the second purge. Then, in the step S15, vacuum-exhaust is performed. The step S13 to step S15 are repeated, as needed, i.e., cycle purge is repeated a predetermined number of times. Thereafter, a Ta₂O₅ film formation process is performed for the next lot of wafers.

In the steps S12 and S14, N₂ gas is supplied through at least one of the first and second supply lines 5a and 5b into the process chamber 21 and exhausted to perform purging. In the step S13, the same conditions as those of the film-formation process on a wafer used in the step S11 are used except for PET gas, so that the environment in the process chamber 21 is prepared. Accordingly, this step is also used for conditioning the environment (environment adjustment) in the process chamber 21 to be closer to that for the film-formation process on the next lot of wafers to be performed in succession. The cycle purge shown in FIG. 9 should be repeated at least three times, because one cycle purge cannot provide a sufficient effect.

An experiment was conducted to confirm the effect of the cycle purge shown FIG. 9. As a reference example, a Ta₂O₅ film formation process was performed on a wafer before idling, and the thin film thus formed on the wafer, i.e., obtained by the step S11, was examined in terms of concentrations of Al, Fe, and Cu. As a comparative example, a thin film formed on a wafer was examined in terms of the metal concentration in the same way, after a long-term idling state, or at the end of the step S12. As a present example, a thin film formed on a wafer was examined in terms of the metal concentration in the same way, after the steps S13 to S15 (cycle purge) shown in FIG. 9 were repeated five times (for five minutes) after idling.

FIG. 10 shows data from the experimental results. As shown in the results, in terms of any one of Al, Fe, and Cu, the present example provided a metal contaminant quantity that was almost equal to that present before idling. It is presumed that, in addition to the ethoxy-compound production described above, another factor is also present, as follows. Specifically, as shown in FIG. 9, the pressure in the process chamber 21 in the step S13 greatly differs from those of the steps S12 and S14 immediately before and after it. The process chamber 21 is exhausted, accompanied by this abrupt pressure change, so that metal chlorides, which cause metal contamination, are thereby separated from parts in the process chamber 21 and exhausted. As a consequence, the metal contaminant quantity to be taken into a thin film is reduced in a subsequent film-formation process.

As described above, the second embodiment is exemplified by a method of forming a tantalum oxide film, using PET as a first process gas (and oxygen as a second process gas). The second embodiment, however, may be applied to a film-formation method that utilizes another organic metal source gas or metal alcoxide, such as a method of forming Ta₂O₅ film or TEOS-SiO₂ film, using Ta(OC₂H₅)₅ or Si(OC₂H₅)₄ as a first process gas, respectively. In these methods, an oxygen-containing gas, such as O₂, O₃, or H₂O, may be used as a second process gas.

As described above, the first and second embodiments reduce the total quantity of contaminants, such as metal, in a film formed on a target substrate after a pre-coating process is performed in the process chamber.

Specifically, in a pre-coating process according to the first and second embodiments, although a first step brings about non-reacted substances dissociated from a process gas and byproducts, which are present within the process chamber or contained in the body of the thin film, a second step exhausts them from the process chamber. As a consequence, it is possible to improve the purity of the composition of a film formed on a target substrate in a subsequent film-formation process.

For example, the second embodiment is explained in an application where a tantalum oxide film is formed, using PET and O₂ gas as process gases. In this case, the second step of the pre-coating process is performed, using oxygen gas, which is a reaction gas, as described in the embodiment, thereby removing carbon in the pre-coat and within the process chamber. Where a tantalum oxide film is formed in the process chamber after a long-term idling state, the second step of the pre-coating process is performed by supplying an inactive gas, as described in the embodiment, thereby removing metal compounds within the process chamber.

On the other hand, according to the first embodiment, the first step of the pre-coating process brings about non-reacted halogenated compounds dissociated from a process gas and halogenated compounds produced as byproducts and taken into a film. The second step reduces the halogenated compounds by, e.g., NH₃ gas, such that halogenated compounds separated by the reduction reaction are exhausted in a gaseous state from the process chamber. As a consequence, metal contamination less likely occurs in a film formed on a target substrate in a subsequent film-formation step.

For example, where a TiN film is formed, NH₃ and TiCl₄ can be used as process gases. In this case, TiClx, HCl, and the like produced in the first step are removed from the process chamber in the second step. As a consequence, the quantity of metal chlorides to be taken in a TiN film is reduced in a subsequent film-formation step.

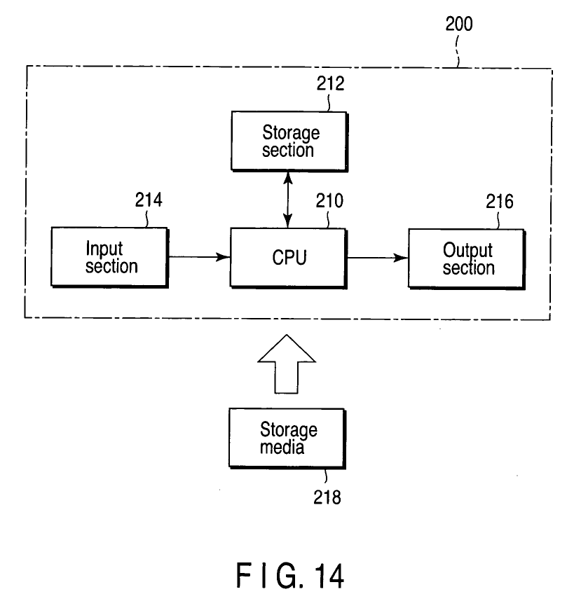

Each of the methods according to the embodiments is performed under the control of the control section 200 (see FIGS. 1 and 6) in accordance with a process program. FIG. 14 is a block diagram schematically showing the structure of the control section 200. The control section 200 includes a CPU 210, which is connected to a storage section 212, an input section 214, and an output section 216. The storage section 212 stores process programs and process recipes. The input section 214 includes input devices, such as a key board, a pointing device, and a storage media drive, to interact with an operator. The output section 216 outputs control signals for controlling components of the semiconductor processing apparatus. FIG. 14 also shows a storage medium or media 218 attached to the computer in a removable state.

Each of the methods according to the embodiments may be written as program instructions for execution on a processor, into a computer readable storage medium or media to be applied to a semiconductor processing apparatus (a film-formation apparatus in this case). Alternately, program instructions of this kind may be transmitted by a communication medium or media and thereby applied to a semiconductor processing apparatus. Examples of the storage medium or media are a magnetic disk (flexible disk, hard disk (a representative of which is a hard disk included in the storage section 212), etc.), an optical disk (CD, DVD, etc.), a magneto-optical disk (MO, etc.), and a semiconductor memory. A computer for controlling the operation of the semiconductor processing apparatus reads program instructions stored in the storage medium or media, and executes them on a processor, thereby performing a corresponding method, as described above.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A film-formation method for a semiconductor process to form a film containing a metal element on a target substrate, which is placed on a worktable in an airtight process chamber, the method comprising:
(a) pre-coating of covering the worktable with a pre-coat before loading the target substrate into the process chamber, the pre-coating comprising
a first step of supplying a first process gas including a source gas containing the metal element into the process chamber, while heating the worktable and exhausting the process chamber, thereby forming a segment film containing the metal element on the worktable, and
a second step of supplying a second process gas including no source gas containing a metal element into the process chamber, while heating the worktable and exhausting the process chamber, thereby exhausting and removing, from the process chamber, a byproduct produced in the first step other than a component forming the segment film,
wherein the first and second steps are repeated a plurality of times, thereby laminating a plurality of segment films to form the pre-coat; and
(b) film formation, after the pre-coating, of loading the target substrate into the process chamber, and forming a main film on the target substrate, the film formation comprising
a step of loading the target substrate into the process chamber and placing the target substrate on the worktable, and
a step of supplying the first and second process gases into the process chamber, while heating the worktable and exhausting the process chamber, thereby forming the main film containing the metal element on the target substrate.

2. The method according to claim 1, wherein the first and second steps employ substantially common process temperature and process pressure, and the byproduct sublimes at the process temperature and process pressure.

3. The method according to claim 1, wherein the first process gas contains a compound of the metal element with a halogen element, the second process gas contains at least nitrogen atoms or hydrogen atoms.

4. The method according to claim 3, wherein the second process gas contains at least one selected form the group consisting of ammonia, N₂, and H₂.

5. The method according to claim 3, wherein the first process gas contains titanium tetrachloride, the second process gas contains ammonia, and the main film consists essentially of a titanium nitride film.

6. The method according to claim 3, wherein the first process gas contains titanium tetrachloride and hydrogen, the second process gas contains hydrogen, and the main film consists essentially of titanium film.

7. The method according to claim 1, wherein the second step is performed by stopping the first process gas and supplying the second process gas into the process chamber, thereby producing the byproduct by reaction of the second process gas with an intermediate produced by decomposition or reaction of the first process gas, and exhausting and removing the byproduct from the process chamber.

8. The method according to claim 1, wherein the first process gas contains an alcoxide of the metal element, and the second process gas contains an oxidizing gas.

9. The method according to claim 8, wherein the first process gas contains pentoethoxytantalum, and the main film consists essentially of a tantalum oxide film.

10. The method according to claim 7, wherein the second step comprises a purge period of exhausting the process chamber, while stopping the first and second process gases.

11. The method according to claim 10, wherein the second step is performed by supplying an inactive gas into the process chamber during the purge period.

12. The method according to claim 8, wherein the first process gas is a gas that produces alcohol by thermal decomposition, and the byproduct is produced by reaction of alcohol, which is produced by decomposition of the first process gas, with a halogenated metal within the process chamber.

13. The method according to claim 1, further comprising, between the pre-coating and the film formation:
an idling step of supplying an inactive gas into the process chamber, while exhausting the process chamber;
a first purge step of supplying a second process gas into the process chamber, while exhausting the process chamber; and
a second purge step of supplying an inactive gas into the process chamber, while exhausting the process chamber,
wherein the first and second purge steps are repeated three times or more.

14. The method according to claim 12, further comprising a cleaning step, before the pre-coating, of supplying a cleaning gas containing a halogen element into the process chamber, thereby cleaning the process chamber, wherein the halogenated metal is derived from the halogen element.

15. A CVD method of forming a film containing a metal element on a target substrate, which is placed on a worktable in an airtight process chamber, by supplying a first process gas containing the metal element and a second process gas that assists decomposition of the first process gas into the process chamber, the method comprising:
(a) pre-coating of covering the worktable with a pre-coat before loading the target substrate into the process chamber, the pre-coating comprising
a first step of supplying the first and second process gases into the process chamber, while heating the worktable and exhausting the process chamber, thereby forming a segment film containing the metal element on the worktable, and
a second step of stopping the first process gas and supplying the second process gas into the process chamber, while heating the worktable and exhausting the process chamber, thereby producing a byproduct by reaction of the second process gas with an intermediate produced by decomposition or reaction of the first process gas, and exhausting and removing the byproduct from the process chamber,
wherein the first and second steps are repeated a plurality of times, thereby laminating a plurality of segment films to form the pre-coat, and
the first and second steps employ substantially common process temperature and process pressure, and the byproduct sublimes at the process temperature and process pressure; and
(b) film formation, after the pre-coating, of loading the target substrate into the process chamber, and forming a main film on the target substrate, the film formation comprising
a step of loading the target substrate into the process chamber and placing the target substrate on the worktable, and
a step of supplying the first and second process gases into the process chamber, while heating the worktable and exhausting the process chamber, thereby forming the main film containing the metal element on the target substrate.

16. The method according to claim 15, wherein the pre-coating is performed by repeating the first and second steps 10 cycles or more.

17. The method according to claim 15, wherein the first process gas contains a compound of the metal element with a halogen element, the second process gas contains at least nitrogen atoms or hydrogen atoms.

18. The method according to claim 15, wherein the first process gas contains an alcoxide of the metal element, and the second process gas contains an oxidizing gas.

19. A computer readable medium containing program instructions for execution on a processor, which when executed by the processor, cause a film-formation apparatus for a semiconductor process to form a film containing a metal element on a target substrate, which is placed on a worktable in an airtight process chamber, the program instructions causing the apparatus to perform:
(a) pre-coating of covering the worktable with a pre-coat before loading the target substrate into the process chamber, the pre-coating comprising
a first step of supplying a first process gas including a source gas containing the metal element into the process chamber, while heating the worktable and exhausting the process chamber, thereby forming a segment film containing the metal element on the worktable, and
a second step of supplying a second process gas including no source gas containing a metal element into the process chamber, while heating the worktable and exhausting the process chamber, thereby exhausting and removing, from the process chamber, a byproduct produced in the first step other than a component forming the segment film,
wherein the first and second steps are repeated a plurality of times, thereby laminating a plurality of segment films to form the pre-coat; and
(b) film formation, after the pre-coating, of loading the target substrate into the process chamber, and forming a main film on the target substrate, the film formation comprising
a step of loading the target substrate into the process chamber and placing the target substrate on the worktable, and
a step of supplying the first and second process gases into the process chamber, while heating the worktable and exhausting the process chamber, thereby forming the main film containing the metal element on the target substrate.

20. A computer readable medium containing program instructions for execution on a processor, which when executed by the processor, cause a CVD apparatus to form a film containing a metal element on a target substrate, which is placed on a worktable in an airtight process chamber, by supplying a first process gas containing the metal element and a second process gas that assists decomposition of the first process gas into the process chamber, the program instructions causing the apparatus to perform:
(a) pre-coating of covering the worktable with a pre-coat before loading the target substrate into the process chamber, the pre-coating comprising
a first step of supplying the first and second process gases into the process chamber, while heating the worktable and exhausting the process chamber, thereby forming a segment film containing the metal element on the worktable, and
a second step of stopping the first process gas and supplying the second process gas into the process chamber, while heating the worktable and exhausting the process chamber, thereby producing a byproduct by reaction of the second process gas with an intermediate produced by decomposition or reaction of the first process gas, and exhausting and removing the byproduct from the process chamber,
wherein the first and second steps are repeated a plurality of times, thereby laminating a plurality of segment films to form the pre-coat, and
the first and second steps employ substantially common process temperature and process pressure, and the byproduct sublimes at the process temperature and process pressure; and
(b) film formation, after the pre-coating, of loading the target substrate into the process chamber, and forming a main film on the target substrate, the film formation comprising
a step of loading the target substrate into the process chamber and placing the target substrate on the worktable, and
a step of supplying the first and second process gases into the process chamber, while heating the worktable and exhausting the process chamber, thereby forming the main film containing the metal element on the target substrate.
